(19) United States
(12) Patent Application Publication
(10) Pub. No.: US 2008/0157845 A1
(43) Pub. Date: Jul. 3, 2008

(54) CLOCK BUFFER CIRCUIT, SEMICONDUCTOR MEMORY DEVICE AND METHOD FOR CONTROLLING AN INPUT THEREOF

(76) Inventor: Sun Suk YANG, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/776,327

(22) Filed: Jul. 11, 2007

(30) Foreign Application Priority Data
Dec. 28, 2006 (KR) 10-2006-0137175

(51) Int. Cl. G11C 8/02; G06F 1/04

(52) U.S. Cl. 327/291; 365/233.1

(57) ABSTRACT

The present invention relates to a semiconductor memory device having a clock buffer circuit which buffers an external clock to generate an internal clock, wherein the clock buffer circuit comprises a rising clock buffer which buffers an external clock to generate a rising internal clock corresponding to a rising edge of the external clock; and a falling clock buffer which buffers the external clock to generate a falling internal clock corresponding to a falling edge of the external clock, whereby the external signal is input to the internal circuit in synchronization with the rising internal clock and the falling internal clock.

### CROSS-REFERENCE TO RELATED APPLICATIONS

The present application claims priority to Korean patent application number 10-2006-0137175 filed on Dec. 28, 2006, which is incorporated herein by reference in its entirety.

### BACKGROUND OF THE INVENTION

The present invention relates to a semiconductor memory device, and more particularly to a semiconductor memory device having a clock buffer circuit which buffers an external clock to generate an internal clock.

In general, a semiconductor memory device is structured such that all external signals are input within the semiconductor memory device in synchronization with rising edges of an internal clock. Therefore, only rising edge of the internal clock has been an important element in setup and hold times. However, it is required to use a double data rate (DDR) configuration in which the external signal is input in synchronization with the rising edges and falling edges of the internal clock, in order to implement various operations within one period of the clock along with high speed operation.

In the semiconductor memory device of DDR configuration, a conventional clock buffer circuit can be structured as shown in FIG. 1.

Referring to FIG. 1, a differential amplifying unit 100 differentially amplifies an external clock (CLK) and an inverted external clock (CLKB) to output a clock (CLK_AMP) having the same phase as the external clock (CLK). The clock (CLK_AMP) output by the differential amplifying unit 100 is delayed and inverted via a delay/inverter unit 120 to output an internal clock (ICLK) and an inverted internal clock (ICLKB). Herein, the inverted external clock (CLKB) and the inverted internal clock (ICLKB) have an opposite phase to that of the external clock (CLK) and the internal clock (ICLK) respectively.

Any one of address, command, and data is latched in synchronization with the rising edges of the internal clock (ICLK) and the inverted internal clock (ICLKB) generated by the delay/inverter unit 120. If the external signal is input in synchronization with the rising edges and the falling edges of the internal clock, the falling edges of the internal clock (ICLK) is also involved in the setup time and the hold time for the latch. Therefore, the differential amplifier unit 100 of a conventional clock buffer circuit can not help in reducing a margin of the setup time and the hold time for the latch.

Meanwhile, a pulse width of the internal clock (ICLK) and the inverted internal clock (ICLKB) can be varied in accordance with external environmental elements, such as PVT (Process, Voltage, and Temperature). In this case, the varied pulse width of the internal clock (ICLK) can have an effect on latching the external signal at the falling edges of the internal clock.

Considering, for example, an address latch used for read operations, if an active command (ACT) is input at a prescribed rising edge (T1) of the external clock (CLK) and a read command (RD) is input at the next rising edge (T2), Ar1, Af1, Ar2, and Af2 of an address (ADDR) are sequentially input starting from the rising edge T1, as shown in FIG. 3.

The address (ADDR) input in synchronization with the external clock (CLK) is buffered to provide the internal address (IADDR), and Ar1 and Ar2 of the internal address (IADDR) are latched at the rising edges of the internal clock (ICLK) for address output by the delay/inverter unit 120 respectively to provide the internal address (IADDR_LAT).

The Ar1, Ar2 of the internal address (IADDR_LAT) and the Af1, Af2 of the internal address (IADDR) are aligned and latched at the rising edge of the inverted internal clock (ICLKB) respectively since ½ tCK to provide internal addresses (RIADDR, FIADDR).

At this time, if a pulse width of the internal clock (ICLK) is reduced due to the external environment, it can reduce a margin of the setup time and the hold time for Af1, Af2 latches of the internal address (IADDR) at the rising edge of an inverted internal clock (ICLKB) which is obtained by inverting the internal clock (ICLK).

That is, the conventional input buffer circuit delays and inverts the clock output (CLK_AMP) generated by the differential amplifying unit 100 via the delay/inverter unit 120 to output the internal clock (ICLK) and the inverted internal clock (ICLKB). Therefore, if the pulse width of the internal clock (ICLK) is reduced due to the external environment, it can reduce the margin of the setup time and the hold time for the latch operation at the rising edge of the inverted internal clock (ICLKB) which is obtained by inverting the internal clock (ICLK), whereby a problem with low reliability is caused.

### SUMMARY OF THE INVENTION

Therefore, the present invention is contemplated to address some of the above problems by securing a large latch margin for input signals by reducing variables caused by an internal clock pulse in the semiconductor memory device in which an external signal is input in synchronization with a rising edge and a falling edge of the internal clock pulse.

The present invention, provides a clock buffer circuit comprising: a rising clock buffer which buffers an external clock to generate a rising internal clock corresponding to a rising edge of the external clock; and a falling clock buffer which buffers the external clock to generate a falling internal clock corresponding to a falling edge of the external clock.

Herein, the external clock comprises any one of address, command and data.

Preferably, the rising clock buffer comprises: a noninverted differential amplifying unit which differentially amplifies the external clock and an differential clock having a phase corresponding to an inverted phase of the external clock thereof to output a clock of same phase as the external clock; and a first delay unit which delays an output clock from the noninverted differential amplifying unit to output the rising internal clock used for an internal synchronization of the external signal.

Preferably, the falling clock buffer comprises: an inverted differential amplifying unit which differentially amplifies the external clock and an differential clock having a phase corresponding to an inverted phase of the external clock thereof to output a clock of same phase as the inverted external clock; and a second delay unit which delays an output clock from the inverted differential amplifying unit to output the falling internal clock used for an internal synchronization of the external signal.

The present invention, can also provide a semiconductor memory device comprising: a rising clock buffer which buffers an external clock to generate a rising internal clock corresponding to a rising edge of the external clock; a falling clock buffer which buffers the external clock to generate a falling internal clock corresponding to a falling edge of the external clock; and a latch circuit which latches an external signal with the rising and falling internal clock.

Preferably, the latch circuit comprises an address buffer which buffers the address to generate an internal signal; a first latch unit which latches the internal signal in synchronization with a rising edge of the rising internal clock; and a second latch unit which aligns and latches an output signal from the first latch unit and an output signal from the address buffer in synchronization with a falling edge of the falling internal clock.

Moreover, the latch circuit comprises an address buffer which buffers the command to generate an internal signal; a first latch which latches the internal signal in synchronization with a rising edge of the rising internal clock; and a second latch which aligns and latches an output signal from the first latch unit and an output signal from the address buffer in synchronization with a rising edge of the falling internal clock.

Moreover, the latch circuit comprises an address buffer which buffers the data to generate an internal signal; a first latch unit which latches the internal signal in synchronization with a rising edge of the rising internal clock; and a second latch unit which aligns and latches an output signal from the first latch unit and an output signal from the address buffer in synchronization with a rising edge of the falling internal clock.

The present invention can also provide a method for controlling an input of the semiconductor memory device comprising the steps of generating a rising internal clock which is synchronized with a rising edge of an external clock; generating a falling internal clock which is synchronized with a falling edge of the external clock; first-latching an external signal input from outside in synchronization with a rising edge of the rising internal clock; and aligning and second-latching the external signal input from the outside and the first-latched external signal in synchronization with a rising edge of the falling internal clock.

Herein, the step of generating the rising clock comprises a step of differentially amplifying the external clock and an differential clock having a phase corresponding to an inverted phase of the external clock thereof to output a clock having same phase as the external clock; a step of delaying the clock having same phase as the external clock to output the rising internal clock.

Preferably, the second step comprises a step of differentially amplifying the external clock and an differential clock having a phase corresponding to an inverted phase of the external clock thereof to output a clock having an opposite phase to the external clock; and a step of delaying the clock having the opposite phase to the external clock to output the falling internal clock.

Preferably, the external signal comprises any one of address, command, and data.

### BRIEF DESCRIPTION OF THE DRAWINGS

FIG. 1 depicts a block diagram showing a clock buffer circuit according to a prior art.

FIG. 2 depicts a waveform diagram illustrating circuit operations of FIG. 1.

FIG. 3 depicts a block diagram showing a semiconductor memory device including a clock buffer circuit according to an embodiment of the present invention.

FIG. 4 depicts a block diagram showing an example of a latch circuit of FIG. 3 corresponding to an address latch.

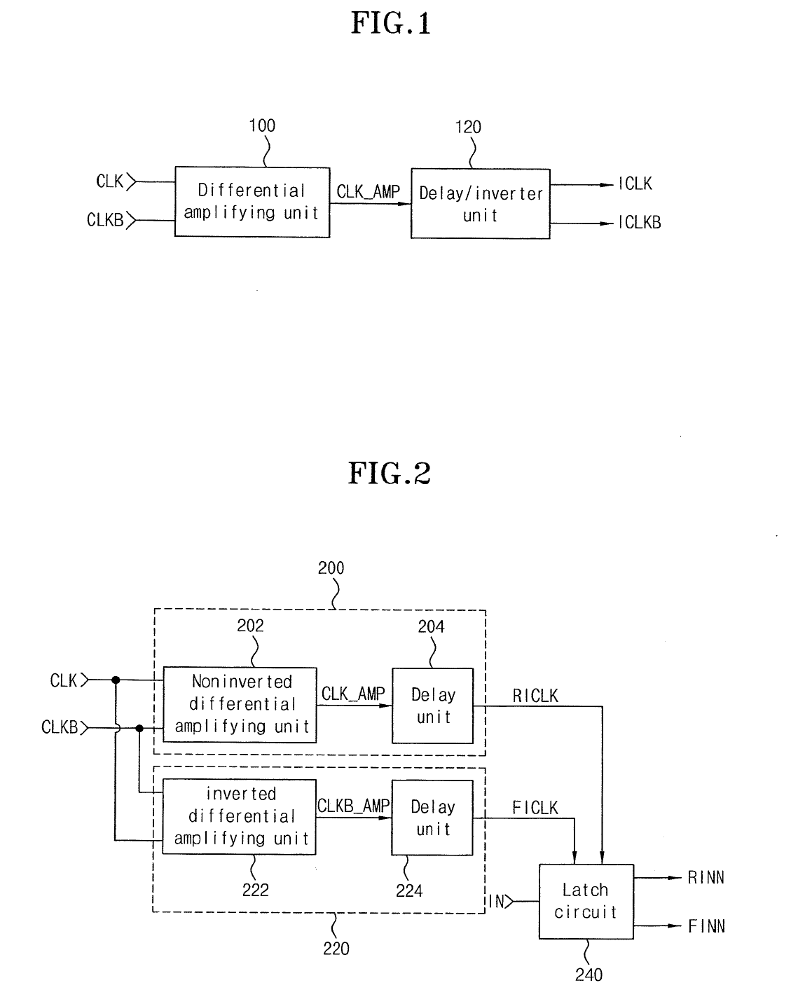

### DESCRIPTION OF SPECIFIC EMBODIMENTS

Hereinafter, preferred embodiments of the present invention will be described in detail with reference to the accompanying drawings.

A semiconductor memory device of the present invention distinctly generates a rising internal clock corresponding to a rising edge of an external clock and an falling internal clock corresponding to a falling edge of the external clock, and performs a latch operation for address, command and data in synchronization with the rising edge of the rising internal clock and the rising edge of the falling internal clock.

More specifically, the semiconductor memory device of the present invention includes a rising clock buffer 200 which buffers the external clock (CLK) to generate a rising internal clock (RICLK) corresponding to the rising edge of an external clock (CLK), a falling clock buffer 220 which buffers an external clock (CLK) to generate a falling internal clock (FICLK) corresponding to the falling edges of the external clock (CLK), and a latch circuit 240 which latches the external signal (IN) at the rising edge of the rising internal clock (RICLK) and the falling internal clock (FICLK) to output an internal rising signal (RINN) and an internal falling signal (FINN).

Herein, the rising clock buffer 200 includes a noninverted differential amplifying unit 202 and a delay unit 204, and the falling clock buffer 220 includes an inverted differential amplifying unit 222 and a delay unit 224.

The noninverted differential amplifying unit 202 differentially amplifies the external clock (CLK) and the inverted external clock (CLKB) to output the clock (CLK_AMP) having same phase to the external clock (CLK). Herein, the noninverted differential amplifying unit 202 may comprise an operational amplifier configured to receive the external clock (CLK) at the noninverted input terminal and to receive the inverted external clock (CLKB) at the inverted input terminal to output a clock (CLK_AMP) which is equal to a difference between the external clock (CLK) and the inverted external clock (CLKB) multiplied by a gain.

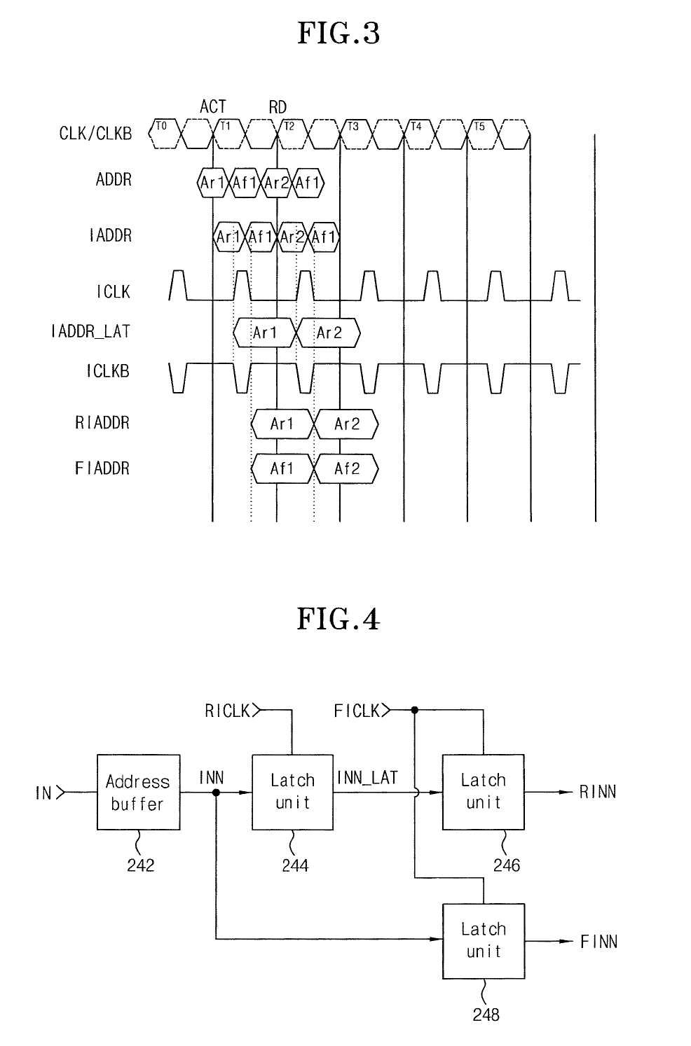

The delay unit 204 delays a clock (CLK_AMP) output by the noninverted differential amplifying unit 202 to output a rising internal clock (RICLK). The delay unit 204 may be composed of a plurality of inverter chains which is input with the clock (CLK_AMP) in common, and the plurality of inverter chains is configured to generate clocks in synchronization with address, command, and data. The rising internal clock RICLK of FIG. 3 means any one of the clocks output by the inverter chains.

The inverted differential amplifying unit 222 differentially amplifies the external clock (CLK) and the inverted external clock (CLKB) to output the clock (CLKB_AMP) having the same phase as the inverted external clock (CLKB). Herein, the inverted differential amplifying unit 222 may be composed of an operational amplifier which are input the inverted external clock (CLKB) at the noninverted input terminal and the inverted external clock (CLK) at the inverted input terminal to output a clock (CLKB_AMP) which is equal to a difference between the inverted external clock (CLKB) and the external clock (CLK) multiplied by a gain.

The delay unit 224 delays the clock (CLKB_AMP) output from the inverted differential amplifying unit 222 to output the falling internal clock (FICLK). The delay unit 224 can be composed of a plurality of inverter chains which is input the clock (CLKB_AMP) in common, and the plurality of inverter chains generate clocks in synchronization with address, command, and data. The falling internal clock (FICLK) of FIG. 3 means any one of clocks output by the inverter chain.

The rising internal clock (RICLK) output from the rising clock buffer 200 and the falling internal clock (FICLK) output from the falling clock buffer 220 are input into the latch circuit 240 to latch the external signal (IN).

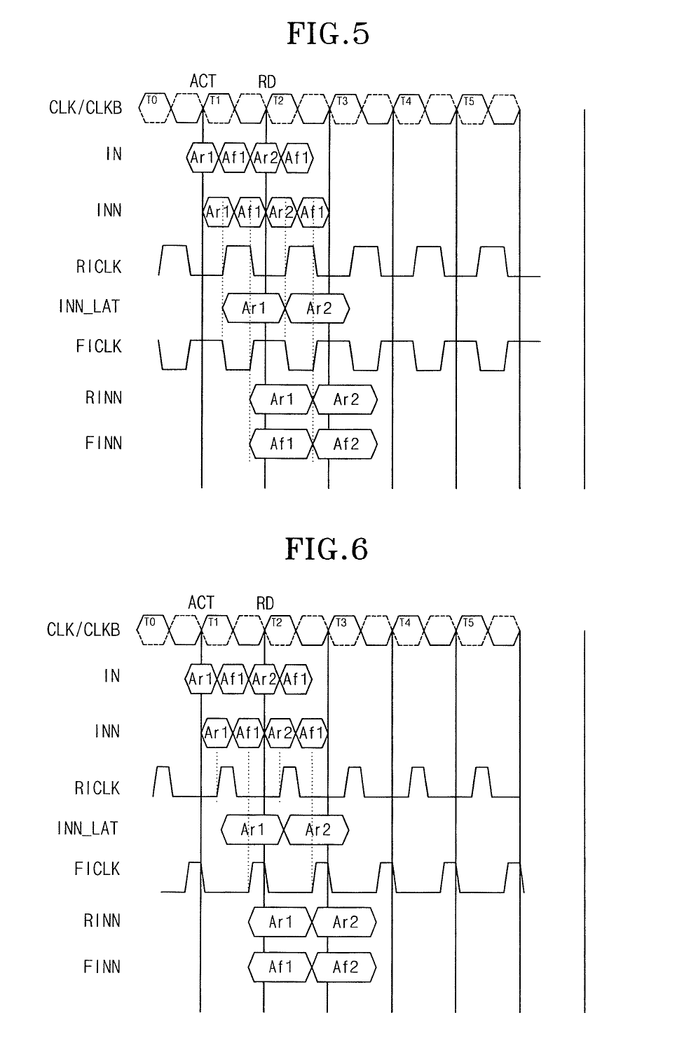

If the rising internal clock (RICLK) and the falling internal clock (FICLK) are used for address latch, the latch circuit 240 located in address path can be composed of an address buffer 242 and three latch units (244, 246, 248) as shown in FIG. 4.

More specifically, referring to FIG. 4, the address buffer 242 outputs a signal input from the outside, that is, an internal address (INN) obtained by buffering the external address.

The latch unit 244 latches the internal address (INN) in synchronization with a rising edge of the rising internal clock (RICLK) to output an internal address (INN_LAT).

The latch unit 246 latches the internal address (INN_LAT) output from the latch unit 244 in synchronization with a rising edge of the falling internal clock (FICLK) to output an internal address (RINN).

The latch unit 248 latches the internal address (INN) in synchronization with a rising edge of the falling internal clock (FICLK) to output a falling internal address (FINN).

Hereinafter, when performing the address latch for read operations with the rising internal clock (RICLK) and the falling internal clock (FICLK) output from the semiconductor memory device, an address (IN) is input in Ar1, Af1, Ar2, and Af2 in sequential order starting from a rising edge (T1).

The input address (IN) is buffered via the address buffer 242 to provide the internal address (INN) which is synchronized with a rising edge of the external clock (CLK). Ar1 and Ar2 of the internal address (INN) are latched at the rising edges of the rising internal clock (RICLK) via the latch unit 244 respectively to provide the internal address (INN_LAT).

Since ½ tCK based on the rising internal clock RICLK is configured to latch Ar1 and Ar2 of the internal address (INN_LAT) at the rising edges of the internal address FICLK via the latch unit 246

The latch unit 248 is configured to simultaneously latch Af1 and Af2 of the internal address (INN) at the rising edge of the falling internal clock (FICLK) and to output a falling internal address FINN.

That is, Ar1, Ar2 of the rising internal address RINN and Af1, Af2 of the falling internal address (FINN) are aligned with the rising edge of the falling internal clock (FICLK) respectively.

As such, the semiconductor memory device of the present invention is configured to distinctly generate the rising internal clock (RICLK) corresponding to the rising edge of the external clock (CLK) and is configured to generate the falling internal clock (FICLK) corresponding to the falling edge of the external clock (CLK) to be used as the latch for address, command and data.

As is shown in FIG. 6, the timed difference between that of the rising edge of the rising internal clock (RICLK) and the rising edge of the falling internal clock (FICLK) used to latch the external signal can be kept similar to a pulse width of the external clock even if a duty of the clock is deviated by the external environment.

Moreover, since the timed difference between the rising edge of the rising internal clock (RICLK) and the rising edge of the falling internal clock (FICLK) is always maintained similar to the pulse of the external clock, it is possible to secure a latch margin of the external input signal in the semiconductor memory device of DDR configuration operating at high speed.

As described above, the present invention applied to the semiconductor memory device of DDR configuration has an advantage in that the setup and hold time margin for the latch operation can be sufficiently secured by using latch operations in which internal clocks corresponding to the rising edge and the falling edge of the external clock are distinctly generated.

Those skilled in the art will appreciate that the specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

What is claimed is:

1. A clock buffer circuit, comprising:
a rising clock buffer buffering an external clock to generate a rising internal clock corresponding to a rising edge of the external clock; and
a falling clock buffer buffering the external clock to generate a falling internal clock corresponding to a falling edge of the external clock.

2. The clock buffer circuit as set forth in claim 1, wherein the external clock comprises any one of address, command, and data.

3. The clock buffer circuit as set forth in claim 1, wherein the rising clock buffer comprises:
a noninverted differential amplifying unit differentially amplifying the external clock and an differential clock having a phase corresponding to an inverted phase of the external clock thereof to output a clock having the same phase of the external clock; and
a first delay unit delaying an output clock from the noninverted differential amplifying unit to output the rising internal clock used for an internal synchronization of the external signal.

4. The clock buffer circuit set forth in claim 1, wherein the falling clock buffer comprises:
an inverted differential amplifying unit differentially amplifying the external clock and an differential clock having a phase corresponding to an inverted phase of the external clock thereof to output a clock having the same phase of the inverted external clock; and
a second delay unit delaying an output clock from the inverted differential amplifying unit to output the falling internal clock used for an internal synchronization of the external signal.

5. A semiconductor memory device, comprising:
a rising clock buffer buffering an external clock to generate a rising internal clock corresponding to a rising edge of the external clock;
a falling clock buffer buffering the external clock to generate a falling internal clock corresponding to a falling edge of the external clock; and
a latch circuit configured to latch an external signal with the rising internal clock and the falling internal clock.

6. The semiconductor memory device as set forth in claim 5, wherein the rising clock buffer comprises:
a noninverted differential amplifying unit differentially amplifying the external clock and an differential clock having a phase corresponding to an inverted phase of the external clock thereof and outputting a clock having same phase of the external clock; and
a first delay unit configured to delay an output clock from the inverted differential amplifying unit to output the rising internal clock.

7. The semiconductor memory device set forth in claim 5, wherein the falling clock buffer comprises:
a inverted differential amplifying unit differentially amplifying the external clock and an differential clock having a phase corresponding to an inverted phase of the external clock thereof and outputting a clock having the same phase of the inverted external clock; and
a second delay unit configured to delay an output clock from the inverted differential amplifying unit to output the falling internal clock.

8. The semiconductor memory device as set forth in claim 5, wherein the external signal comprises an address input from outside.

9. The semiconductor memory device set forth in claim 8, wherein the latch circuit comprises:
an address buffer buffering the address to generate an internal signal;
a first latch unit configured to latch the internal signal in synchronization with a rising edge of the rising internal clock; and
a second latch unit configured to align and latch an output signal from the first latch unit and an output signal from the address buffer in synchronization with a falling edge of the falling internal clock.

10. The semiconductor memory device as set forth in claim 5, wherein the external signal comprises a command input from outside.

11. The semiconductor memory device as set forth in claim 10, wherein the latch circuit comprises:
an address buffer buffering the command to generate an internal signal;
a first latch configured to latch the internal signal in synchronization with a rising edge of the rising internal clock; and
a second latch configured to align and latch an output signal from the first latch unit and an output signal from the address buffer in synchronization with a rising edge of the falling internal clock.

12. The semiconductor memory device as set forth in claim 5, wherein the external signal comprises data input from outside.

13. The semiconductor memory device as set forth in claim 12, wherein the latch circuit comprises:
an address buffer buffering the data to generate an internal signal;
a first latch unit configured to latch the internal signal in synchronization with a rising edge of the rising internal clock; and
a second latch unit configured to align and latch an output signal from the first latch unit and an output signal from the address buffer in synchronization with a rising edge of the falling internal clock.

14. A method for controlling an input of the semiconductor memory device, the method comprising the steps of:
generating a rising internal clock which is synchronized with a rising edge of an external clock;
generating a falling internal clock which is synchronized with a falling edge of the external clock;
first-latching an external signal input from outside in synchronization with a rising edge of the rising internal clock; and
aligning and second-latching the external signal input from the outside and the first-latched external signal in synchronization with a rising edge of the falling internal clock.

15. The method for controlling an input of the semiconductor memory device as set forth in claim 14, wherein the step of generating a rising internal clock comprises:
differentially amplifying the external clock and an differential clock having a phase corresponding to an inverted phase of the external clock thereof to output a clock having same phase as the external clock; and
delaying the clock having same phase as the external clock to output the rising internal clock.

16. The method for controlling an input of the semiconductor memory device as set forth in claim 14, wherein the step of generating a falling internal clock comprises:
differentially amplifying the external clock and an differential clock having a phase corresponding to an inverted phase of the external clock thereof to output a clock having an opposite phase to the external clock; and
delaying the clock having the opposite phase to the external clock to output the falling internal clock.

17. The method for controlling an input of the semiconductor memory device as set forth in claim 14, wherein the external signal comprises any one of address, command, and data.
